(19) United States
(12) Patent Application Publication
(10) Pub. No.: US 2015/0364623 A1
(43) Pub. Date: Dec. 17, 2015

(54) SOLAR CELL MODULE PRODUCTION METHOD

(71) Applicant: Panasonic Intellectual Property Management Co., Ltd., Osaka (JP)

(72) Inventors: Satoshi SUZUKI, Osaka (JP); Yoshiyuki KUDOH, Shiga (JP); Masaya NAKAI, Shiga (JP)

(21) Appl. No.: 14/834,877

(22) Filed: Aug. 25, 2015

Related U.S. Application Data
(63) Continuation of application No. PCT/JP2014/000654, filed on Feb. 7, 2014.

(30) Foreign Application Priority Data
Feb. 28, 2013 (JP) 2013-039778

(51) Int. Cl. H01L 31/0224; H01L 31/18; H01L 31/05

(52) U.S. Cl. CPC H01L 31/022425; H01L 31/0504; H01L 31/18

(57) ABSTRACT

A solar cell module production method involves applying adhesives on a light-receiving surface and a rear surface of a solar cell having electrodes on the light-receiving surface and the rear surface, and positioning and attaching a wiring material on the adhesives. Specifically, the adhesives are applied via screen printing, and different screen plates are used on the light-receiving surface side and the rear surface side to apply a greater amount of adhesive on the rear surface side than on the light-receiving surface side.

### CROSS-REFERENCE TO RELATED APPLICATION

The present application is a continuation under 35 U.S.C. §120 of PCT/JP2014/000654, filed Feb. 7, 2014, which is incorporated herein by reference and which claimed priority to Japanese Patent Application No. 2013-039778 filed Feb. 28, 2013. The present application likewise claims priority under 35 U.S.C. §119 to Japanese Patent Application No. 2013-039778 filed Feb. 28, 2013, the entire content of which is also incorporated herein by reference.

### TECHNICAL FIELD

The present invention relates to a solar cell module production method.

### BACKGROUND ART

A solar cell module includes a plurality of solar cells, a wiring material which connects the solar cells with one another, and an encapsulant which seals these solar cells and wiring material, and the like. The wiring material is bonded on electrodes of the solar cell, and solder has been mainly used for this bonding. However, the effects of heat during soldering can cause warping and cracking of the solar cell. Such defects appear more significantly the thinner the solar cells are. Therefore, a method has been proposed (e.g., see Patent Literature 1) which uses a resin adhesive (hereinafter simply referred to as an “adhesive”), instead of solder, to bond a wiring material and a solar cell with each other.

### CITATION LIST

### Patent Literature

### Patent Literature 1: Japanese Patent Laid-Open Publication No. 2008-205137

### SUMMARY OF INVENTION

### Technical Problem

When electrodes are to be provided on both sides of a solar cell, it is necessary to apply an adhesive to both sides of the solar cell. In this case, depending on the adhesive application method, for example, the visual quality of the solar cell after application may be affected, or an unfavorable effect on the performance of the solar cell module may be caused, such as qualitative abnormality due to decrease in bonding strength of the wiring material or deterioration of the photoelectric conversion characteristics due to increase in contact resistance of the wiring material. Thus, rationalization of the adhesive application method is an important issue in the production process of solar cell modules.

### Solution to Problem

A solar cell module production method according to the present invention involves applying an adhesive to a light-receiving surface and a rear surface of a solar cell having electrodes on the light-receiving surface and the rear surface, and disposing a wiring material on the adhesive to bond the wiring material, wherein the adhesive is applied by screen printing, using different screen plates for the light-receiving surface side and the rear surface side, so as to apply a larger amount of adhesive to the rear surface side than to the light-receiving surface side.

### Advantageous Effects of Invention

According to the present invention, it is possible to improve the performance of a solar cell module, for example, the photoelectric conversion characteristics, reliability, etc., by rationalizing the adhesive application method.

### BRIEF DESCRIPTION OF DRAWINGS

FIG. 1 is a sectional view of a solar cell module which is one example of the embodiment of the present invention.

FIG. 2A is a view from the light-receiving surface side (front view) of a solar cell of the solar cell module of FIG. 1.

FIG. 2B is a view from the rear surface side (rear view) of the solar cell of the solar cell module of FIG. 1.

FIG. 3 is a view showing a part of the section along the line AA of FIGS. 2A and 2B.

FIG. 4A is a view illustrating a production step of the solar cell module which is one example of the embodiment of the present invention.

FIG. 4B is a view illustrating a production step of the solar cell module which is one example of the embodiment of the present invention.

FIG. 5A is a view illustrating a production step of the solar cell module which is one example of the embodiment of the present invention.

FIG. 5B is a view illustrating a production step of the solar cell module which is one example of the embodiment of the present invention.

FIG. 6 is a view illustrating a production step of the solar cell module which is one example of the embodiment of the present invention.

FIG. 7A is a view showing a first modified example of the adhesive application pattern.

FIG. 7B is a view showing a second modified example of the adhesive application pattern.

FIG. 7C is a view showing a third modified example of the adhesive application pattern.

FIG. 7D is a view showing a fourth modified example of the adhesive application pattern.

### DESCRIPTION OF EMBODIMENTS

In the following, embodiments according to the present invention will be described in detail with reference to the drawings.

The drawings to be referred to in the embodiments are schematically described, and the dimensional ratios etc. of the components depicted in these drawings may be different from those of the actual components. The specific dimensional ratios etc. should be determined in consideration of the following description.

In this specification, a “light-receiving surface” means a surface through which sunlight mainly enters from the outside of a solar cell. A “rear surface” means a surface opposite to the light-receiving surface. To be more specific, more than 50% to 100% of the sunlight entering the solar cell enters from the light-receiving surface side.

Unless otherwise noted, an “upper side” means the vertically upper side.

To take “substantially the same” for example, it is intended that the word “substantially” refers not only to being completely the same but also to being recognized as virtually the same.

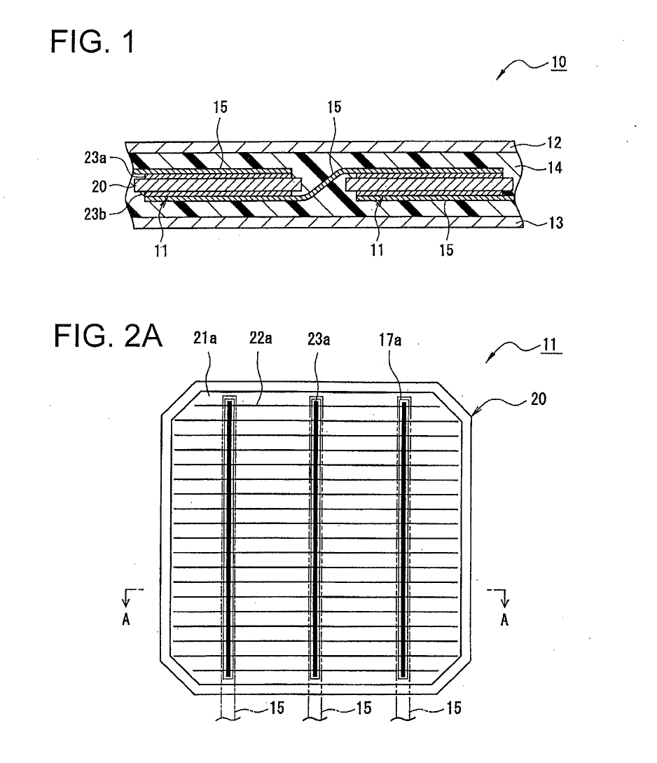

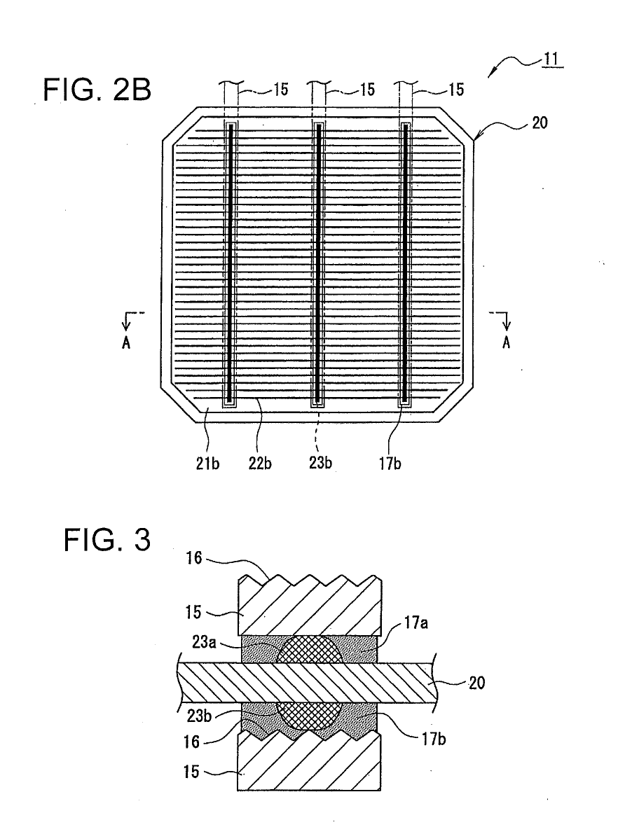

FIG. 1 is a sectional view of a solar cell module 10 which is one example of the embodiment of the present invention. FIGS. 2A and 2B are views of a solar cell 11 of the solar cell module 10, from the light-receiving surface side and the rear surface side, respectively (wiring materials 15 are indicated by a dash-dot line). FIG. 3 is a view showing the section along the line AA of FIGS. 2A and 2B. The solar cell module 10 to be described below using FIG. 1 to FIG. 3 is an example of a product manufactured by a production method to be described later.

As shown in FIG. 1, the solar cell module 10 includes a plurality of solar cells 11, a first protection member 12 which is disposed on the light-receiving surface side of the solar cell 11, and a second protection member 13 which is disposed on the rear surface side of the solar cell 11. The plurality of solar cells 11 are held between the protection members 12, 13 and sealed by a encapsulant 14 such as ethylene-vinyl acetate copolymer (EVA). For the protection members 12, 13, a member having translucency, for example, a glass substrate, a resin substrate, a resin film, etc. can be used. In a case where no entry of light from the rear surface side is assumed, a member having no translucency may be used for the protection member 13. The solar cell module 10 further includes the wiring material 15 which electrically connects the solar cells 11 with one another, a frame (not shown), a terminal box (not shown), etc.

The solar cell 11 includes a photoelectric conversion part 20 which generates carriers upon receiving sunlight. The photoelectric conversion part 20 has a semiconductor substrate of crystalline silicon (c-Si), gallium arsenide (GaAs), indium phosphide (InP), or the like, and a non-crystalline semiconductor layer formed on the substrate. The photoelectric conversion part 20 preferably has transparent conductive layers 21a, 21b formed on the non-crystalline semiconductor layer. Specific examples include a structure in which an i-type non-crystalline silicon layer, a p-type non-crystalline silicon layer, and the transparent conductive layer 21a are sequentially formed on the light-receiving surface of an n-type single-crystal silicon substrate, and an i-type non-crystalline silicon layer, an n-type non-crystalline silicon layer, and the transparent conductive layer 21b are sequentially formed on the rear surface. It is preferable that the transparent conductive layers 21a, 21b are composed of a transparent conductive oxide obtained by doping a metal oxide such as an indium oxide (In₂O₃), a zinc oxide (ZnO), etc. with tin (Sn), antimony (Sb), or the like.

As shown in FIGS. 2A and 2B, it is preferable that finger electrodes 22a and bus bar electrodes 23a as light-receiving surface electrodes, and finger electrodes 22b and bus bar electrodes 23b as rear surface electrodes, are provided on the photoelectric conversion part 20. The finger electrodes 22a, 22b are thin-line-shaped electrodes formed over a wide area of the transparent conductive layers 21a, 21b, respectively. The bus bar electrodes 23a, 23b are electrodes which collect carriers from the finger electrodes 22a, 22b, respectively. In a case where the bus bar electrodes 23a, 23b are provided, the wiring material 15 is mounted on these electrodes.

In this embodiment, three bus bar electrodes 23a are disposed substantially parallel to one another at predetermined intervals, and a large number of finger electrodes 22a are disposed substantially orthogonally to these bus bar electrodes 23a. All the electrodes have a linear shape. While the electrode arrangement of the rear surface electrodes is similar to that of the light-receiving surface electrodes, since the effect of shadow loss on the photoelectric conversion characteristics is smaller on the rear surface than on the light-receiving surface, the rear surface electrodes can be formed to have a larger area than the light-receiving surface electrodes. For example, the rear surface electrodes have an electrode area about two to six times as large as that of the light-receiving surface electrodes, and the number of the finger electrodes 22b can be made larger than the number of the finger electrodes 22a. That is to say, the “light-receiving surface” is a surface with a smaller electrode area, and the “rear surface” is a surface with a larger electrode area.

The electrode has a structure, for example, in which a conductive filler such as silver (Ag) is dispersed inside a binder resin. As with an adhesive 17 to be described later, electrodes of this structure can be formed by screen printing. In a case where no entry of light from the rear surface side is assumed, a metal layer of Ag etc. formed over substantially the entire area of the transparent conductive layer 21b may serve as the rear surface electrode.

The wiring material 15 is a long thin member which connects adjacently-disposed solar cells 11 with each other. One end of the wiring material 15 is mounted on the bus bar electrode 23a of one solar cell 11 of adjacently-disposed solar cells 11. The other end of the wiring material 15 is mounted on the bus bar electrode 23b of the other solar cell 11. That is, the wiring material 15 is bent in the direction of the thickness of the solar cell module 10 between adjacently-disposed solar cells 11, and connects these solar cells 11 in series (see FIG. 1).

As shown in FIG. 3, it is preferable that one surface of the wiring material 15 is substantially flat and the other surface has roughness 16. The wiring material 15 is disposed so that the roughness 16 faces the side of the protection member 12. That is, the flat surface of the wiring material 15 is bonded on the light-receiving surface, and the surface with the roughness 16 is bonded on the rear surface. With the wiring material 15 thus disposed, light diffused on the roughness 16 is reflected again off the protection member 12 toward the side of the solar cell 11, so that the light reception efficiency of the solar cell 11 can be enhanced.

The wiring material 15 is bonded on the bus bar electrodes 23a, 23b by means of adhesives 17a, 17b, respectively. The long thin wiring material 15 is disposed along the longitudinal direction of the bus bar electrodes 23a, 23b so that the centers in the width direction of the wiring material 15 and the bus bar electrodes 23a, 23b substantially coincide with each other. Since the wiring material 15 is required to be strong enough at least not to be cut during production or use, for example, the width of the wiring material 15 is set to a larger width than the width of the bus bar electrodes 23a, 23b. Accordingly, the wiring material 15 is mounted while projecting from both sides in the width direction of the bus bar electrodes 23a, 23b.

For the adhesives 17a, 17b, a thermoplastic adhesive, thermal curing adhesive, cold-curing adhesive (moisture curing type, two-component curing type), and energy ray curing adhesive (ultraviolet curing type) can be used. Of these adhesives, a curing adhesive is preferable and a thermal curing adhesive is especially preferable. Examples of the thermal curing adhesive include a urea adhesive, resorcinol adhesive, melanin adhesive, phenolic adhesive, epoxy adhesive, polyurethane adhesive, polyester adhesive, polyimide adhesive, and acrylic adhesive. In the following, the adhesives 17a, 17b are described as thermal curing adhesives.

While the adhesives 17a, 17b may contain a conductive filler such as Ag particles, from the viewpoint of the production cost and reduction of shadow loss, the adhesives 17a, 17b are preferably non-conductive thermal curing adhesives which contain no conductive filler. The adhesives 17a, 17b before curing (hereinafter, the adhesives before curing will be referred to as “adhesives 40a, 40b”) are in a liquid state. It is intended for the expression “liquid state” to refer not only to states with fluidity at room temperature (25° C.) but also to a so-called paste state and gel state.

It is preferable that the adhesives 17a, 17b are present only between the wiring material 15 and the light-receiving surface and between the wiring material 15 and the rear surface, respectively. That is, it is preferable that the adhesives 17a, 17b do not protrude from between the wiring material 15 and the light-receiving surface and between the wiring material 15 and the rear surface, respectively, and that there is no so-called fillet, which is an adhesive adhering to the side surfaces of the wiring material 15. This is not only because the wiring material 15 has to be bonded firmly on the solar cell 11, but also, from the viewpoint of stress relief etc., it is preferable that the wiring material 15 is bonded loosely to such an extent that it does not detach during production or use. That is, while it is important to control the bonding strength between the wiring material 15 and the solar cell 11 to a proper range, if a fillet is formed, bonding by the fillet becomes dominant and it becomes difficult to control the bonding strength. In this embodiment, since the adhesive is applied so as not to protrude from the wiring material 15, it is easy to control the bonding strength to a proper range. The “stress” which should be relieved is mainly shear stress occurring at the interface between the wiring material 15 and the solar cell 11 due to changes in volume (expansion/contraction due to temperature changes) of the encapsulant 14.

The amount of adhesive 17b is preferably larger than the amount of adhesive 17a. In particular, when the surface with the roughness 16 of the wiring material 15 is bonded on the rear surface, the amount of adhesive 17b is preferably larger than the amount of adhesive 17a by at least an amount corresponding to the concave portions of the roughness 16. Thus, the adhesive 17b is packed into the concave portions as well, so that favorable bonding between the wiring material 15 and the rear surface can be realized without forming a fillet.

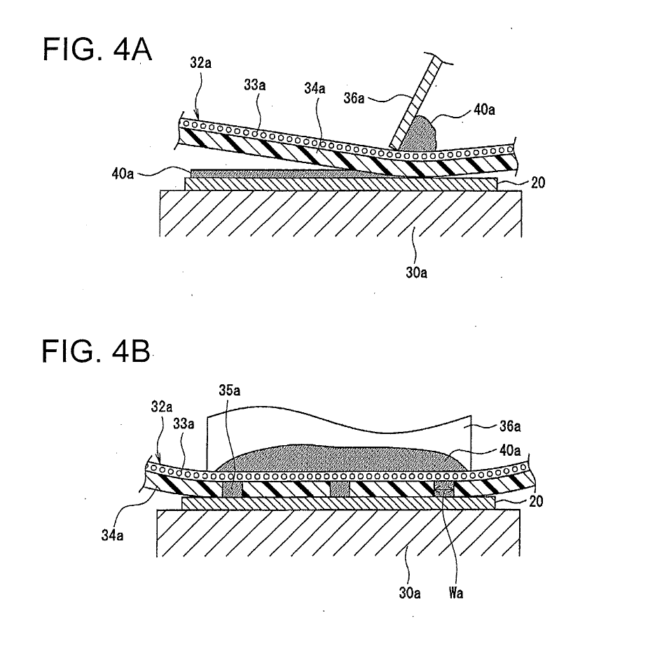

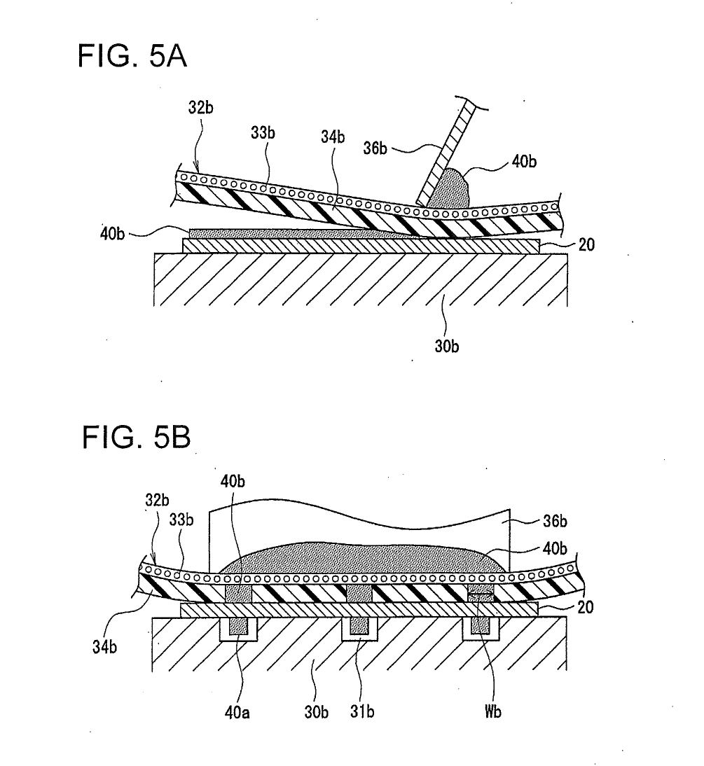

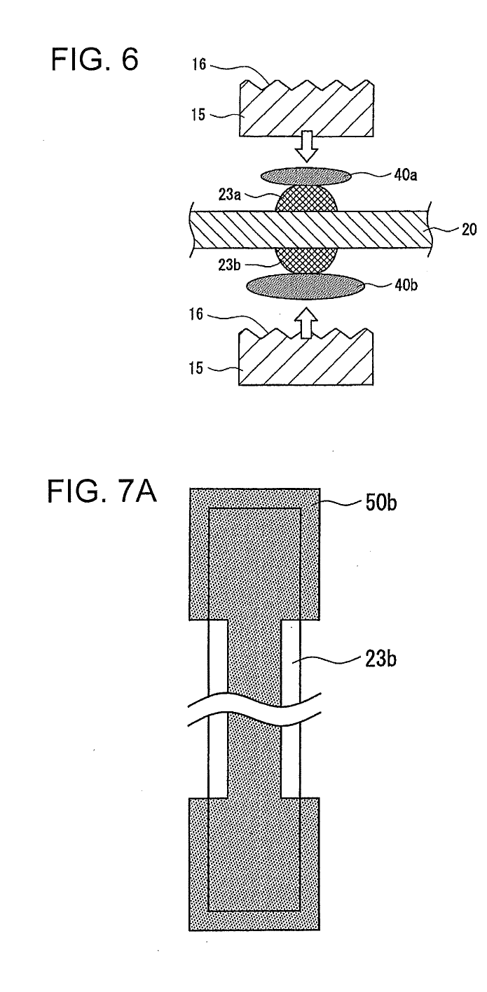

In the following, a production method of the solar cell module 10 which is one example of the embodiment of the present invention will be described with reference to FIG. 4 to FIG. 6. FIG. 4 shows a step of applying the adhesive 17a to the light-receiving surface of the solar cell 11 (hereinafter referred to as “step A”), and FIG. 5 shows a step of applying the adhesive 17b to the rear surface of the solar cell 11 (hereinafter referred to as “step B”). FIGS. 4A and 5A is a sectional view of a screen plate etc. cut along the longitudinal direction of the bus bar electrodes 23a, 23b, and FIGS. 4B and 5B is a sectional view of the screen plate etc. cut along the direction orthogonal to the longitudinal direction. FIG. 6 is a view showing a step of bonding the wiring material 15. Steps A and B will be collectively referred to as the “present application step”.

In the present application step, steps A and B are performed using two printing devices. However, steps A and B may be performed using one printing device which is equipped with a plurality of screen plates. Hereinafter, an uncured adhesive applied to the light-receiving surface will be referred to as the “adhesive 40a”, and an uncured adhesive applied to the rear surface will be referred to as the “adhesive 40b”. The adhesives 40a, 40b correspond to the adhesives 17a, 17b, respectively, and these terms will also be used before the adhesives are transferred onto the light-receiving surface and the rear surface.

In the present application step, the adhesives 40a, 40b are applied to the light-receiving surface and the rear surface, respectively, by screen printing. The use of screen printing allows the adhesives 40a, 40b to be efficiently applied to intended positions. In the present application step, off-contact printing will be described, but on-contact printing can also be used. In the following, contents which are common to steps A and B will be described with step A taken as an example.

As shown in FIG. 4, in step A, the adhesive 40a is applied to the light-receiving surface of the solar cell 11 disposed on a stage 30a. The solar cell 11 is disposed on the stage 30a with its light-receiving surface facing upward. In this embodiment, the adhesive 40a is preferably applied to the bus bar electrodes 23a along the longitudinal direction of the electrodes. The adhesive 40a is applied, for example, in continuous lines of substantially the same width, so as to be slightly wider than the bus bar electrodes 23a.

In step A, a common screen printing device having a screen plate 32a, a squeegee 36a, etc. can be used to apply the adhesive 40a to the light-receiving surface. As will be described in detail later, in step A, the squeegee 36a is slid over the screen plate 32a and the adhesive 40a is printed on the light-receiving surface at intended positions. The squeegee 36a is preferably slid along the longitudinal direction of the bus bar electrode 23a.

The screen plate 32a has a mesh 33a which is a fabric etc. transmitting the adhesive 40a, and a frame (not shown) with the mesh 33a stretched across it. A masking material 34a is provided on the mesh 33a so as to correspond to regions of the light-receiving surface where application of the adhesive 40a is not desired. That is, opening portions 35a corresponding to the formation pattern of the adhesive 40a are formed in the screen plate 32a. More specifically, the screen plate 32a has three opening portions 35a which are formed substantially parallel to one another at predetermined intervals. Each opening portion 35a has a longitudinal length which is almost the same as the longitudinal length of the bus bar electrode 23a, and a width Wa which is larger than the width of the bus bar electrode 23a and is smaller than the width of the wiring material 15.

The mesh 33a is composed, for example, of a resin fiber of polyester etc. or a metal wire of stainless steel etc. The wire diameter, mesh count, opening ratio etc. of the mesh 33a are appropriately selected according to the width, thickness, etc. of the intended adhesive 40a.

For example, a photosensitive emulsion is used for the masking material 34a. The emulsion is selected according to the resolution, exposure sensitivity, etc., and, for example, a diazo or stilbazolium material is used. The thickness of the masking material 34a is appropriately selected according to the thickness etc. of the intended adhesive 40a.

In step A, the adhesive 40a is placed on the screen plate 32a in which the opening portions 35a are formed, and the squeegee 36a is slid to thereby pack the adhesive 40a into the opening portions 35a as well as to press the screen plate 32a against the light-receiving surface. Then, at the time of so-called plate release, when a portion of the screen plate 32a over which the squeegee 36 has passed is separated from the light-receiving surface, the adhesive 40a is discharged from the opening portions 35a and transferred onto the light-receiving surface. Thus, the adhesive 40a is printed on the light-receiving surface in an intended pattern. The adhesive 40a remains uncured until being heated with the wiring material 15 disposed on it.

In step A, it is preferable that the width Wa of the opening portion 35a is smaller than the width of the wiring material 15, and that the amount of application of the adhesive 40a is adjusted so that the adhesive 40a does not protrude from between the wiring material 15 and the light-receiving surface. That is, the amount of application should be such that the adhesive 40a is not pushed out from between the wiring material 15 and the light-receiving surface when the wiring material 15 is thermally press-bonded in a later step. Thus, it is possible to prevent formation of fillets and adjust the bonding strength between the wiring material 15 and the light-receiving surface to a proper range from the viewpoint of stress relief etc. In particular, the light-receiving surface side preferably has no fillet from the viewpoint of the visual quality and shadow loss as well.

It is preferable that the solar cell 11 is reversed so that the rear surface faces upward during the period after completion of step A until the start of step B. That is, it is preferable that a mechanism for reversing the solar cell 11 is provided between the printing device used in step A and the printing device used in step B, or at least in one of the printing devices.

As shown in FIG. 5, in step B, the adhesive 40b is applied to the rear surface of the solar cell 11 disposed on a stage 30b. The solar cell 11 is disposed on the stage 30b with its rear surface facing upward. In this embodiment, the adhesive 40b is preferably applied to the bus bar electrodes 23b along the longitudinal direction of the electrodes. The adhesive 40b is applied, for example, in continuous lines of substantially the same width, so as to be slightly wider than the bus bar electrodes 23b. It is preferable that a groove 31b corresponding to the formation pattern of the adhesive 40a is formed in the stage 30b in advance so that the adhesive 40a previously applied in step A does not adhere to the stage 30b. In this embodiment, three long thin grooves 31b are formed in the stage 30b.

In step B, as in step A, a common screen printing device can be used to apply the adhesive 40b to the rear surface. In the present application step, different screen plates are used for the light-receiving surface side and the rear surface side. That is, in step B, a screen plate 32b, which is different from the screen plate 32a, is used to apply the adhesive 40b.

In step B, the screen plate 32b is used to apply a larger amount of adhesive than in step A. That is, the amount of application of the adhesives should satisfy the relation: the adhesive 40a<the adhesive 40b. In other words, a smaller amount of adhesive is applied in step A than in step B. As described above, when the surface with the roughness 16 of the wiring material 15 is bonded on the rear surface, the amount of adhesive 17b is preferably larger than the amount of adhesive 17a by at least an amount corresponding to the volume of the concave portions of the roughness 16. If similar amounts of adhesives are applied to the light-receiving surface side and the rear surface side, defects would occur such as formation of fillets on the light-receiving surface side or deterioration of the property of the adhesive 17b filling the concave portions. Such defects can be prevented by applying amounts of adhesives which satisfy the following relation: the adhesive 40b≈the adhesive 40a+the amount corresponding to the volume of the concave portions of the roughness 16.

In this embodiment, since damage or contamination on the light-receiving surface side are more likely to affect the photoelectric conversion characteristics than those on the rear surface side, it is preferable that the solar cell 11 is transported over a transport line with its light-receiving surface facing upward. Therefore, until the wiring material 15 has cured, the wiring material 15 is more likely to detach on the rear surface side than on the light-receiving surface side. From this viewpoint as well, it is preferable that the amounts of application of the adhesives satisfy the relation: the adhesive 40a<the adhesive 40b.

In step B also, it is preferable that a width Wb of an opening portion 35b is smaller than the width of the wiring material 15, and that the amount of application of the adhesive 40b is adjusted so that the adhesive 40b does not protrude from between the wiring material 15 and the rear surface. That is, the amount of application should be such that the adhesive 40b is packed into the concave portions of the roughness 16 while not being pushed out from between the wiring material 15 and the rear surface when the wiring material 15 is thermally press-bonded in a later step. Thus, it is possible to prevent formation of fillets and realize favorable bonding between the wiring material 15 and the rear surface without forming fillets.

The following are examples of the preferred method for achieving the amounts of application of the adhesives which satisfy the relation the adhesive 40a<the adhesive 40b using different screen plates for the light-receiving surface side and the rear surface side.

(1) Make the width Wb of the opening portion 35b of the screen plate 32b larger than the width Wa of the opening portion 35a of the screen plate 32a. According to this method, it is possible to achieve the amounts of application which satisfy the relation the adhesive 40a<the adhesive 40b by simply making the width of the adhesive 40b larger than the width of the adhesive 40a. More specifically, the width Wb is set to such a width that the adhesive 40b does not protrude from the area of the wiring material 15 and is packed into the concave portions of the roughness 16 (the same applies to (2) and (3) below).

(2) Make the thickness of the masking material 34b of the screen plate 32b larger than the thickness of the masking material 34a of the screen plate 32a. According to this method, it is possible to achieve the amounts of application which satisfy the relation the adhesive 40a<the adhesive 40b by simply making the thickness of the adhesive 40b larger than the thickness of the adhesive 40a.

(3) Use a mesh which has a smaller mesh count and a higher opening ratio than the mesh 33a of the screen plate 32a as the mesh 33b of the screen plate 32b. According to this method, it is possible to achieve the amounts of application which satisfy the relation the adhesive 40a<the adhesive 40b, as the ease of application of the adhesive 40b becomes higher than that of the adhesive 40a.

In step B, it is preferable that the amount of application is adjusted by using, as necessary, a plurality of methods as described above in combination. One example is to make the width Wb of the opening portion 35b larger than the width Wa of the opening portion 35a, and at the same time make the thickness of the masking material 34b larger than the thickness of the masking material 34a. Thus, it is possible, for example, to increase the amount of adhesive 40b while keeping the width of the adhesive 40b in a constant range, which makes it easy to prevent formation of fillets while filling the concave portions of the roughness 16 with the adhesive 40b.

In screen printing, parameters which determine the printing conditions include, other than the selection of the screen plate, the squeegee angle, squeegee speed, squeegee printing pressure, and clearance, which is the distance between the screen plate and the solar cell 11. For example, it is also possible to adjust the amount of application by changing these parameters between steps A and B. However, since the adjustment of these parameters is complicated compared with the adjustment of the screen plate, it is more efficient to adjust the amount of application by changing the screen plates between steps A and B as described above.

In the present application step, different adhesives may be used for steps A and B. One such example is to use an adhesive having lower viscosity than the adhesive 40a for the adhesive 40b. Thus, for example, the property of the adhesive 40b filling the concave portions improves.

As shown in FIG. 6, in a step following the present application step, the wiring material 15 is mounted on the solar cell 11 to which the adhesives 40a, 40b have been applied. Of the wiring material 15, the flat surface is bonded on the adhesive 40a and the surface with the roughness 16 is bonded on the adhesive 40b. The wiring material 15 is, for example, thermally press-bonded on the adhesive 40a and the adhesive 40b, and the heating temperature is set to a temperature at which the adhesives 40a, 40b cure. The wiring material 15 may be bonded separately on the light-receiving surface side and the rear surface side of the solar cell 11, or may be bonded at the same time on the light-receiving surface side and the rear surface side of the solar cell 11. At this point, the adhesives 40a, 40b are present only between the wiring material 15 and the light-receiving surface and between the wiring material 15 and the rear surface, respectively, and are not pushed out of the clearance. Moreover, the adhesive 40b is packed into the concave portions of the roughness 16. That is, since the amounts of application satisfy the relation the adhesive 40a<the adhesive 40b, it is possible to prevent formation of fillets on every surface while allowing the adhesive 40b to fill the concave portions. Thus, a string of the plurality of solar cells 11, connected with one another through the wiring material 15 with proper bonding strength, is created.

Next, the components of the solar cell module 10 including the above-mentioned string are stacked and thermally press-bonded. This step is called a lamination step. In the lamination step, a first resin film constituting the encapsulant 14 is stacked on the protection member 12, and the string is stacked on the first resin film. Moreover, a second resin film constituting the encapsulant 14 is stacked on the string, and the protection member 13 is stacked on the second resin film. Then, this stack is laminated by pressurization while being heated at a temperature at which the resin films melt. Thus, a structure with the string sealed by the encapsulant 14 is obtained. Finally, the frame, the terminal box, etc. are mounted and the solar cell module 10 is produced.

As has been described, according to these production steps, it is possible to improve the performance of the solar cell module 10, for example, the photoelectric conversion characteristics, the reliability, etc., by rationalizing the application method of the adhesives 40a, 40b. According to these production steps, it is possible to prevent formation of fillets and control the bonding strength between the wiring material 15 and the solar cell 11 to a proper range from the viewpoint of stress relief etc.

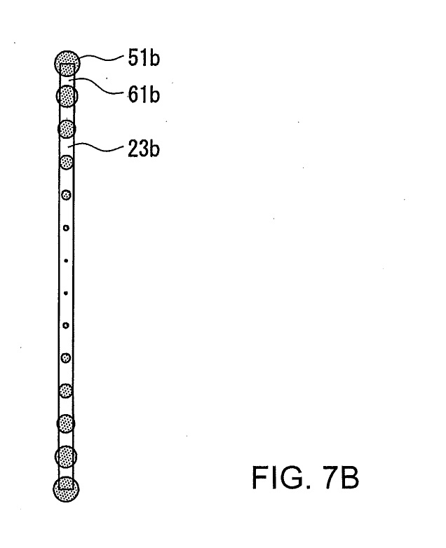

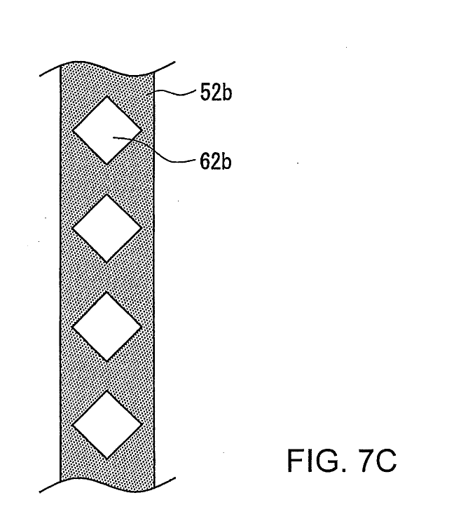

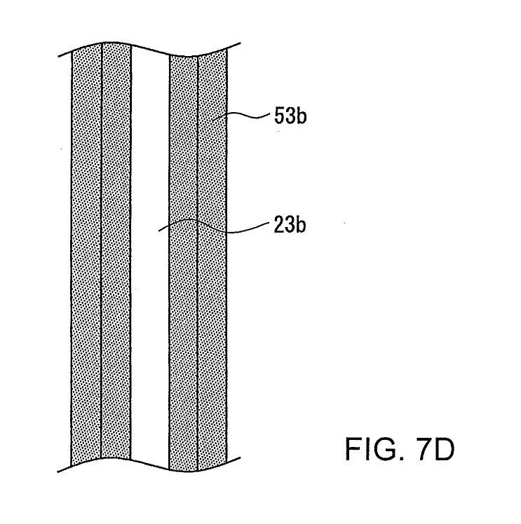

Design changes can be appropriately added to the above-described embodiment within a scope which does not harm the object of the present invention. For example, in the above-described embodiment, the adhesives are applied in continuous lines of substantially the same width. However, the adhesives may be applied in patterns as illustrated in FIGS. 7A to 7D. While FIGS. 7A to 7D show the patterns of adhesives 50b to 53b applied to the rear surface, the same patterns can be adopted for the light-receiving surface side. An alternative is to adopt the patterns of the adhesives 50b to 53b for only the rear surface side and adopt the pattern of the adhesive 17a for the light-receiving surface side.

In the examples shown in FIGS. 7A and 7B, the adhesives are applied in a line extending in one direction, with a larger amount of the adhesives applied at both ends than in a central part in the longitudinal direction of the line. Since the wiring material 15 is likely to detach near the ends of the solar cell 11, this configuration can efficiently suppress detachment of the wiring material 15. More specifically, the width of the adhesive 50b is locally larger at both ends in the longitudinal direction (e.g., within a range of 10% to 15% or less of the entire length). On the other hand, the adhesive 51b is applied in discontinuous dots along the longitudinal direction of the bus bar electrode 23b, and has a plurality of non-application portions 61b along the longitudinal direction. The amount of application of the adhesive 51b increases and the diameter of the dot increases toward both ends in the longitudinal direction. While the adhesive 51b shown in FIG. 7B is in substantially circular dots, the shape of the dots is not limited to this example and may be, for example, an elliptical shape, polygonal shape, thin-line shape, etc.

In the example shown in FIG. 7C, as with the adhesive 51b, a plurality of non-application portions 62b are provided along the longitudinal direction of the adhesive 52b which is applied in a line. For example, the provision of the non-application portions makes it easy to relieve the above-mentioned shear stress. The adhesive 52b is different from the adhesive 51b in that the adhesive 52b is applied continuously along the longitudinal direction and that non-application portions 62b are formed inside the continuous application portion. While the non-application portions 62b have a substantially lozenge shape, the shape may be, for example, a circular shape, elliptical shape, triangular shape, hexagonal shape, etc.

In the example shown in FIG. 7D, the adhesive 53b is applied in two lines which are substantially parallel to each other. While the adhesive 53b shown in FIG. 7D is applied in the pattern of continuous lines of substantially the same width with a clearance left in a central part in the width direction of the bus bar electrode 23b, the number of the lines may be three or more and the lines may intersect with one another.

### REFERENCE SIGNS LIST

10 Solar cell module
11 Solar cell
12, 13 Protection member
14 Encapsulant
15 Wiring material
16 Roughness
17a, 17b, 40, 40a, 40b Adhesive
20 Photoelectric conversion part
21a, 21b Transparent conductive layer
22a, 22b Finger electrode
23a, 23b Bus bar electrode
30a, 30b Stage
31b Groove
32a, 32b Screen plate
33a, 33b Mesh
34a, 34b Masking material
35a, 35b Opening portion
36a, 36b Squeegee

1. A solar cell module production method which involves applying an adhesive to a light-receiving surface and a rear surface of a solar cell having electrodes on the light-receiving surface and the rear surface, and disposing a wiring material on the adhesive to bond the wiring material, wherein
the adhesive is applied by screen printing, and
different screen plates are used for the light-receiving surface side and the rear surface side so as to apply a larger amount of adhesive to the rear surface side than to the light-receiving surface side.

2. The solar cell module production method according to claim 1, wherein
one surface of the wiring material is substantially flat and the other surface has roughness, and
the one surface is bonded on the light-receiving surface and the other surface is bonded on the rear surface.

3. The solar cell module production method according to claim 1, wherein the adhesive is in a liquid state.

4. The solar cell module production method according to claim 1, wherein the width of an opening in the screen plate is smaller than the width of the wiring material, and the amount of application of the adhesive is adjusted so that the adhesive does not protrude from between the wiring material and the light-receiving surface and between the wiring material and the rear surface.

5. The solar cell module production method according to claim 1, wherein the adhesive is applied in a line extending in one direction, with a larger amount of adhesive applied at both ends than in a central part in the longitudinal direction of the line.

6. The solar cell module production method according to claim 1, wherein the adhesive is applied in a line extending in one direction, and a plurality of non-application portions are provided along the longitudinal direction of the line.

7. A solar cell module comprising:
a plurality of solar cells having a light-receiving surface-side electrode and a rear surface-side electrode;
a wiring material which connects the light-receiving surface-side electrode of one solar cell, of adjacent ones of the plurality of solar cells, and the rear surface-side electrode of another solar cell with each other; and
an adhesive which bonds the light-receiving surface-side electrode and the rear surface-side electrode with the wiring material, wherein
one surface of the wiring material is substantially flat and the other surface has roughness, and the one surface is bonded on the light-receiving surface-side electrode and the other surface is bonded on the rear surface-side electrode, and
the amount of application of the adhesive is larger on the rear surface side than on the light-receiving surface side of the solar cell.
